(19) United States
(12) Patent Application Publication
(10) Pub. No.: US 2007/0278484 A1
(43) Pub. Date: Dec. 6, 2007

(54) METHOD AND TEST STRUCTURE FOR ESTIMATING ELECTROMIGRATION EFFECTS CAUSED BY POROUS BARRIER MATERIALS

(76) Inventors: Frank Feustel, Dresden (DE); Christine Hau-Riege, Fremont, CA (US); Tobias Letz, Dresden (DE)

Correspondence Address: J. Mike Amerson, Williams,;Morgan & Amerson P.C., Suite 1100, 10333 Richmond, Houston, TX, 77042, US

(21) Appl. No.: 11/626,705

(22) Filed: Jan. 24, 2007

(30) Foreign Application Priority Data
May 31, 2006 (DE) 10 2006 025 365.5

(51) Int. Cl. H01L 23/58; H01L 21/66

(52) U.S. Cl. 257/48; 438/18; 438/17

(57) ABSTRACT

By providing a test structure for electromigration tests in semiconductor devices, which may indicate the status of a barrier layer at the bottom of a test via in the structure, a significantly increased reliability of respective electromigration tests may be obtained. Furthermore, the degree of porosity of the barrier layer may be estimated on the basis of the resulting test structure, which comprises a feed line having an increased probability for void formation compared to the test via, when a specific degree of porosity is created in the test via.

### BACKGROUND OF THE INVENTION

1. Field of the Invention

Generally, the present disclosure relates to the formation of microstructures, such as advanced integrated circuits, and, more particularly, to the formation and examination of conductive structures, such as metal regions, and their characteristics during stress conditions.

2. Description of the Related Art

In the fabrication of modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption. As the size of individual circuit elements is reduced with every new circuit generation, thereby improving, for example, the switching speed of the transistor elements, the available floor space for interconnect lines electrically connecting the individual circuit elements is also decreased. Consequently, the dimensions of these interconnect lines have to be reduced to compensate for a reduced amount of available floor space and for an increased number of circuit elements provided per unit die area. The reduced cross-sectional area of the interconnect lines, possibly in combination with an increase of the static power consumption of extremely scaled transistor elements, may require a plurality of stacked metallization layers to meet the requirements in view of a tolerable current density in the metal lines.

Advanced integrated circuits, including transistor elements having a critical dimension of 0.13 μm and even less, may, however, require significantly increased current densities in the individual interconnect lines, despite the provision of a relatively large number of metallization layers, owing to the significant number of circuit elements per unit area. Operating the interconnect lines at elevated current densities, however, may entail a plurality of problems related to stress-induced line degradation, which may finally lead to a premature failure of the integrated circuit. One prominent phenomenon in this respect is the current-induced material transportation in metal regions, i.e., lines and vias, also referred to as “electromigration,” which may lead to the formation of voids within and hillocks or protrusions next to the metal region, thereby resulting in reduced performance and reliability or complete failure of the device. For instance, aluminum lines and vias embedded into silicon dioxide and/or silicon nitride are frequently used as metal for metallization layers, wherein, as explained above, advanced integrated circuits having critical dimensions of 0.18 μm or less may require significantly reduced cross-sectional areas of the metal lines and, thus, increased current densities, which may render aluminum less attractive for the formation of metallization layers.

Consequently, aluminum is increasingly being replaced by copper, as copper exhibits a significantly lower resistivity and exhibits significant electromigration effects at considerably higher current densities as compared to aluminum. The introduction of copper into the fabrication of microstructures and integrated circuits comes along with a plurality of severe problems residing in copper's characteristic to readily diffuse in silicon dioxide and a plurality of low-k dielectric materials. To provide the necessary adhesion and to avoid the undesired diffusion of copper atoms into sensitive device regions, it is, therefore, usually necessary to provide a barrier layer between the copper and the dielectric material in which the copper lines and vias are embedded. Although silicon nitride is a dielectric material that effectively prevents the diffusion of copper atoms, selecting silicon nitride as an interlayer dielectric material is less then desirable, since silicon nitride exhibits a moderately high permittivity, thereby increasing the parasitic capacitance of neighboring copper lines. Hence, a thin conductive barrier layer that also imparts the required mechanical stability to the copper is formed to separate the bulk copper from the surrounding dielectric material and only a thin silicon nitride or silicon carbide or silicon carbon nitride layer in the form of a capping layer is frequently used in copper-based metallization layers. Currently, tantalum, titanium, tungsten, tungsten/cobalt/phosphorous compounds, tungsten/cobalt/boron compounds, and their compounds with nitrogen and silicon and the like, are preferred candidates for a conductive barrier layer, wherein the barrier layer may comprise two or more sub-layers of different composition so as to meet the requirements in terms of diffusion suppressing and adhesion properties.

Another characteristic of copper, significantly distinguishing it from aluminum, is the fact that copper may not be readily deposited in large amounts by chemical and physical vapor deposition techniques, in addition to the fact that copper may not be efficiently patterned by anisotropic dry etch processes, thereby requiring a process strategy that is commonly referred to as the damascene or inlaid technique. In the damascene process, first, a dielectric layer is formed which is then patterned to include trenches and vias which are subsequently filled with copper or copper alloys, wherein, as previously noted, prior to filling in the copper-based metal, a conductive barrier layer is formed within the trenches and vias. The deposition of the bulk copper material into the trenches and vias is usually accomplished by wet chemical deposition processes, such as electroplating and electroless plating, thereby requiring the reliable filling of vias with an aspect ratio of 5 and more with a diameter of 0.1 μm or even less in combination with trenches having a width ranging from 0.1 to several μm. Although electrochemical deposition processes for copper are well established in the field of electronic circuit board fabrication, a substantially void-free filling of high aspect ratio vias is an extremely complex and challenging task, wherein the characteristics of the finally obtained copper metal line significantly depend on process parameters, materials and geometry of the structure of interest. Since the dimensions of interconnect structures are determined by the design requirements and may, therefore, not be significantly altered for a given microstructure, it is of great importance to estimate and control the impact of materials, such as conductive and non-conductive barrier layers, of the copper-based microstructure and their mutual interaction on the characteristics of the interconnect structure so as to insure both high yield and the required product reliability. In particular, it is important to identify and monitor degradation and failure mechanisms in interconnect structures for various configurations to maintain device reliability for every new device generation or technology node.

Accordingly, a great deal of effort has been invested in the past decades in investigating the degradation of copper lines and vias, especially in view of electromigration, in order to find new materials and process strategies for forming copper-based metal lines and vias. Although the exact mechanism of electromigration in copper lines and vias is still not quite fully understood, it turns out that voids positioned in and on sidewalls and interfaces and voids and residuals at the via bottom may have a significant impact on production yield and reliability. Except for gross failures, such defects in vias, which may be provided in the form of via chains as control monitor structures in wafer scribe lines, are difficult to detect in standard electrical testing procedures. Thus, great efforts are made in designing appropriately configured test structures in order to estimate the electromigration behavior of vias and to estimate the expected time to failure for vias and metal lines, wherein the results may be indicative for the specifics of actual metallization structures only when well-defined conditions may be established in the test structure. Otherwise, the respective test results may lead to substantially meaningless statements with respect to the actual circuit features. For example, for estimating the mean time to failure of a via and a line connected thereto, which are manufactured according to a specific process flow on the basis of specified materials, such as copper, aluminum, silver and the like, including specific barrier materials, a test structure is formed on the basis of the specific process flow, wherein the design of the test structure is selected such that an electromigration-induced failure, i.e., a respective flux divergence of the material flux in the line or via, is caused in a specified section of the test structure only. Thus, by applying well-defined stress conditions, such as temperature and an injected current, the respective section may be monitored with respect to a resistance increase that may indicate an electromigration-induced void formation and thus a line or via failure.

With reference to FIGS. 1a-1b, a typical conventional test structure for estimating electromigration effects in metallization layers of semiconductor devices will now be described in more detail in order to demonstrate the principles and the problems associated with the conventional test regime.

FIG. 1a schematically illustrates a cross sectional view of a test structure 100 comprising a substrate 101, which may represent any appropriate substrate for forming semiconductor devices or any other microstructural features which require a metallization layer for providing electrical connections in accordance with a specific circuit layout. For instance, the substrate 101 may represent a semiconductor substrate, such as a silicon substrate, having formed thereon a respective semiconductor layer suitable for the formation of circuit elements, such as transistors, capacitors and the like. A first dielectric layer 102, which may be comprised of any appropriate dielectric material as may be used in the metallization layer under consideration, is formed above the substrate 101 and may represent the dielectric material of a respective metallization layer. For instance, the dielectric layer 102 may be formed on the basis of the same process techniques and materials as are used for metallization layers in other substrates or the layer 102 may represent a portion of a metallization layer of a semiconductor device including the test structure 100 at a specific substrate location. Moreover, a metal line 103, also referred to as feed line, may be formed within the dielectric layer 102 and may have specified dimensions and characteristics so as to exhibit a reduced probability for suffering from electromigration effects, such as metal diffusion, when subjected to predefined test conditions.

As previously explained, electromigration effects are the subject of extensive investigations over several decades, wherein it was recognized that electromigration, originating from the interaction of the moving electrons with diffusing metal atoms, thereby exerting a net force on the diffusing metal atoms at high charge carrier densities, may be one dominant reason for premature device failure, thus requiring efficient mechanisms for identifying and avoiding or reducing metal line and via degradation mechanisms. For example, since electromigration is an interaction between electrons and diffusing metal atoms, increased diffusion activity, for instance due to increased temperature, an increased degree of lattice defects, or in general due to the presence of increased diffusion paths, such as grain boundaries, respective interfaces and the like, is an important aspect, and electromigration is highly dependent on the specific manufacturing techniques and materials used. In advanced semiconductor devices, the dimensions of the respective vias and metal lines may also have a significant influence on the finally achieved degree of material transport within the metal lines. Although in modern semiconductor devices copper and copper alloys are frequently used which exhibit a significantly higher resistance against electromigration and have a lower electrical resistance, the ongoing reduction in line width has resulted in moderately high current densities, also causing a high degree of electromigration in copper-based metallization layers. Since a plurality of complex mechanisms may, therefore, have a significant influence on the electromigration behavior, such as grain size, grain orientation, type of barrier material used, type of dielectric barrier materials and the like, it is of great importance to effectively monitor manufacturing techniques in order to control and improve product reliability. Thus, specifically designed test structures have been developed which may obtain meaningful estimations on the electromigration characteristics.

Consequently, the feed line 103 is typically configured such that, with respect to the respective electromigration conditions, a corresponding material transport may not occur in the feed line 103. For this purpose, in conventional techniques, the feed line 103 is configured, for instance, such that the Blech length is not exceeded, which defines a characteristic length below which no material transport through electromigration effects may occur.

Moreover, the test structure 100 may comprise a hook-up or connector line 104, which may be connected to the feed line 103 on the basis of respective vias 105, wherein the connector line 104 has dimensions that may be significantly greater compared to the dimensions of a respective test metal line 106, which is connected to the feed line 103 by a test via 107. The test via 107 and the metal line 106 may be dimensioned in accordance with design rules of actual circuit elements in order to assess a corresponding time to failure of the respective product devices on the basis of the test structure 100. Due to the configuration of the feed line 103 and the large dimensions of the connector line 104, which may be connected to an appropriate probe pad (not shown), it is in principle ensured that any electromigration effects, such as void formation caused by material transport, may take place in the test via 107 and the corresponding test metal line 106. Since, typically, the test structure 100 is formed in accordance with actual manufacturing processes, the respective metal components 105, 104, 107 and 106 may be formed in a respective dielectric layer 108 which may be formed on a respective etch stop layer 109, wherein an additional capping layer or etch stop layer 110 may confine the metal lines 104 and 106.

FIG. 1b schematically illustrates a top view of the test structure 100 as shown in FIG. 1a, wherein a voltage tap 111 is shown which is connected to the feed line 103 or which may be connected to the connector line 104, depending on design requirements. As is evident from FIG. 1b, the connector line 104 is connected with a plurality of vias 105 to the feed line 103, which in turn has an appropriate length so as to avoid any material transport due to electromigration during specified stress conditions, such as specified current density injected into the test via 107 and the metal line 106.

The test structure 100 may be formed on the basis of well-established techniques, wherein, in sophisticated applications, a so-called inlaid or damascene technique may be used for forming copper-based metal regions, wherein, as previously explained, an appropriate conductive barrier layer, such as the layer 112, may be provided in order to obtain the required characteristics with respect to the suppression of diffusion of copper into the dielectric material and of diffusion of reactive components into the copper-based metal regions, wherein, additionally, the characteristics of the barrier layer 112 may significantly affect the electromigration behavior.

During operation of the test structure 100, a respective current may be injected into the test structure 100, for instance by connecting a respective probe pad (not shown), that is connected to the connector line 104, with an appropriate current source which may cause an electron flow from the connector line 104 to the metal line 106 via the feed line 103 and the via 107, wherein the metal line 106 may also be connected to a respective probe pad having appropriate dimensions. By means of the voltage tap 111, a respective resistance increase may be detected which indicates a corresponding void formation in the via 107 and/or the metal line 106 since these components are expected to be the “weakest” members of the entire conductive path from one probe pad to the other. Consequently, a respective threshold for the resistance change may be defined and may thus be used as an indication for a failure of the via 107 and/or the metal line 106, from which a respective time to failure may be derived. In practice, the corresponding time to failures and, thus, the reliability metrics derived from the test structure 100, may in some cases, especially for extremely scaled metallization structures involving the formation of respective barrier layers, lead to unrealistic predictions for actual devices, thereby rendering the corresponding test structure 100 as well as the test procedure associated therewith as less reliable and, thus, cost extensive.

The present disclosure is directed to various methods and systems that may solve, or at least reduce, some or all of the aforementioned problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to a technique for assessing electromigration effects of complex metallization structures, wherein vias and metal lines are provided that comprise a barrier layer, wherein characteristics of the barrier layer within the test via may be assessed by providing an appropriately designed test structure. It has been recognized that, in conventional test structures including a test via and a metal line formed on the basis of a barrier layer, the degree of coverage of the barrier layer at the bottom of the via may significantly affect the overall behavior of a conventional test structure. For instance, the presence of porous areas or holes within the barrier layer at the via bottom may result in the formation of a void in the feed line due to the modified electrical characteristics of the via owing to the missing or at least partially missing barrier layer at the bottom, which may, for instance, reduce the series resistance from the feed line to the via and may also weaken the respective confinement of the feed line, which would otherwise be obtained when the respective barrier layer is intact. Since the electromigration failure may have shifted from the actual test structure to the feed line, the finally obtained time to failure from the respective test structure may result in apparently longer lifetimes compared to a test structure having a substantially continuously covered test via. In order to reduce the deleterious effects of defective barrier layers on the assessment of electromigration effects on the basis of a respective test structure, a respective feed line is provided which may have the highest probability of all involved electrical components in the test structure for void formation, when a respective test via of the test structure may have a defective barrier layer at its bottom. For this purpose, the respective feed line may be configured such that void formation will occur first in the feed line when the respective test via of the test structure has a porous barrier layer or a hole in the barrier at the bottom of the via. Consequently, upon performing an electromigration test on the basis of a defective barrier layer within the test via, a rapid increase of resistance may be detected in the feed line which may, therefore, indicate a respective barrier failure so that the corresponding test result may be analyzed by taking into account the respective barrier failure. Hence, significantly more reliable assessments of a test structure with respect to electromigration may be obtained.

According to one illustrative embodiment disclosed herein, a test structure comprises a test via and a test metal line connected therewith, wherein the test via and the test metal line are formed in a metallization layer located above a substrate that is appropriate for forming semiconductor devices for an integrated circuit thereon. Moreover, the test via and the test metal line comprise a conductive barrier layer. Additionally, a feed line is connected to the test via, wherein a cross-section area of the feed line is less than a cross-section area of the test metal line. Furthermore, the test structure comprises a connector line connected to the feed line.

According to another illustrative embodiment disclosed herein, a test structure for estimating electromigration effects in a metallization layer of a semiconductor device comprises a first test via comprising a barrier layer and a metal. Moreover, a first feed line is provided and is connected to the first test via, wherein the first feed line is configured to have a first higher probability for void formation compared to the first test via, when the barrier layer is substantially non-continuously formed on a bottom of the first test via, thereby providing a substantially non-continuous interface with the feed line.

According to yet another illustrative embodiment disclosed herein, a method comprises injecting a specified current into a test structure, wherein the test structure comprises a first test via and a first feed line connected to the first test via, wherein the first feed line has a higher probability for void formation during injecting the specified current compared to the first test via when lacking a substantially continuous barrier layer on a bottom thereof. The method further comprises obtaining a first resistance change at a first position and a second resistance change at a second position of the first feed line. Finally, a status of the barrier layer at the bottom of the first test via is estimated on the basis of the first and second resistance changes.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a conventional test structure formed in a metallization layer formed in accordance with a process flow for forming semiconductor devices, wherein a test via and a test metal line are connected to a respective probe pad on the basis of a feed line having a specified configuration to suppress electromigration effects, when the test via is reliably connected to the feed line by means of a barrier layer;

FIG. 1b schematically illustrates a top view of the test structure of FIG. 1a;

FIGS. 2a-2b schematically illustrate cross-sectional views of a test structure during various manufacturing stages comprising a test via and a test metal line connected to a feed line having a higher probability for electromigration failure, when a non-continuous barrier layer is provided at the bottom according to illustrative embodiments disclosed herein;

FIG. 2c schematically illustrates a top view of the test structure shown in FIGS. 2a-2b;

FIG. 2d schematically illustrates a cross-sectional view of the test structure as shown in FIG. 2c during operation according to illustrative embodiments disclosed herein; and

FIG. 2e schematically illustrates a test structure including a plurality of test vias and test metal lines connected to respective feed lines having different probabilities for electromigration failure according to yet other illustrative embodiments disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein relates to a technique for enhancing the capability of electromigration test procedures in order to obtain assessments of the test structure under consideration with increased reliability. As previously explained, electromigration is a highly complex dynamic process, in which the momentum exchange between charge carriers, that is electrons in metals, and diffusing metal atoms may result in a directed motion of the diffusing atoms when a sufficiently high current density is achieved. Due to the reduced cross-sectional areas of metal lines and vias in sophisticated integrated circuits and the fact that, in principle, the respective metal lines are confined in a respective dielectric material allowing an efficient heat transfer into the surrounding chip area, extremely high current densities of approximately 10⁶ ampere/cm² may be achieved which brings about significant electromigration effects. Consequently, unless the metallization structure of respective semiconductor devices is designed and manufactured in such a way that respectively high current density may be reliably avoided in any metal region of the semiconductor device, a significant electromigration may occur during the operation of the respective semiconductor device. However, a corresponding design of semiconductor devices would significantly reduce the design flexibility and would require reduced packing densities, thereby significantly reducing performance and cost efficiency of the respective semiconductor devices. Consequently, a compromise is typically made between performance and packing density with respect to electromigration in that, instead of manufacturing substantially “immortal” metallization structures, design and manufacturing criteria are selected such that a desired lifetime under specific operation conditions may be achieved. As a consequence, it is extremely important to reliably estimate the expected lifetime of the metallization structures of semiconductor devices, which is typically performed on the basis of respective test structures operated on the basis of stress conditions involving high current densities and high temperatures, wherein the time to failure may provide an indication for the lifetime of the respective metallization structures under real operational conditions.

Although certain theoretical models of the electromigration kinetics have been established, for instance known under Black's law, which indicates a relationship between a typical time to failure and the square of the inverse currents densities, which quantitatively describes the effect of electromigration for a certain class of conditions, for instance metal lines without confining barrier layers and the like, with moderate precision, and other effects, such as the Blech effect, have been discovered which completely avoids electromigration effects when the length of a metal region at a specific current density is selected so as to be equal or higher than a so-called critical product of the length and the current density, it nevertheless turns out that, due to the significant influence of diffusion on the finally obtained electromigration effect, a theoretical prediction of the finally obtained time to failure is extremely complex and may not be sufficient to reliably estimate the characteristics of complex metallization structures as typically used in sophisticated integrated circuits. Even the configuration of a respective test structure may have a significant influence on the outcome of the respective lifetime test, wherein, for instance, an incorrectly predicted time to failure during corresponding electromigration tests may result in an incorrectly predicted lifetime of the actual semiconductor devices, thereby contributing to a reduced reliability of the respective products, which may result in a significant economic risk for the semiconductor manufacturer.

According to the subject matter disclosed herein, an enhanced technique for estimating the time to failure during electromigration tests may be achieved on the basis of a test structure, in which the status of a respective barrier layer in a test via may be reliably estimated in the context of the electromigration test in order to assess the reliability of the corresponding test results. Moreover, in some illustrative embodiments, the degree of barrier corruption in the respective test vias may be estimated on the basis of the test structure. For this purpose, contrary to conventional designs, an additional “bottle neck” is provided within the actual test structure including a test via so as to achieve a high probability for void formation in the bottle neck feed line, when the test via lacks a substantially continuous barrier layer especially on a bottom side thereof. Consequently, during a respective electromigration test, a respective resist change within the feed line may be detected in order to estimate the presence of a substantially non-continuous barrier layer in the test via. In this way, the quality of the test vias and, thus, of the vias of the actual metallization structure may be estimated while, at the same time, additionally meaningful lifetime results may be obtained from the respective test structure, since it may be recognized whether or not a barrier failure outside the bottle neck feed line has occurred.

It should be appreciated that the subject matter disclosed herein is highly advantageous in the context of sophisticated semiconductor devices requiring a metallization structure, for instance based on copper, copper alloys and other highly conductive metals, in combination with circuit elements having critical dimensions of 100 nm and significantly less, since, here, highly complex manufacturing procedures, such as inlaid techniques in the form of single or dual damascene processes, are typically used during the fabrication of metallization layers. For instance, in combination with a plurality of metals, such as copper and copper alloys, formed in accordance with single or dual inlaid techniques, an appropriate barrier layer usually has to be formed within respective via openings and trench openings prior to filling in the highly conductive metal. During the deposition of the barrier metal, process non-uniformities, especially at respective via bottoms, may thus represent a critical field of the entire manufacturing process, since these critical device areas may lead to a nonrealistic lifetime estimation, thereby producing a high probability for premature failure in actual products. It should be appreciated, however, that the principles of the present invention may be readily applied to any type of metallization layer irrespective of the specifics of the materials used and of the manufacturing technique employed, as long as metal vias are provided in which a barrier layer is required, the characteristics of which may significantly affect the overall electromigration behavior. Thus, unless explicitly set forth in the specification and the appended claims, the present invention should not be considered as being restricted to copper-based metallization structures formed on the basis of inlaid techniques.

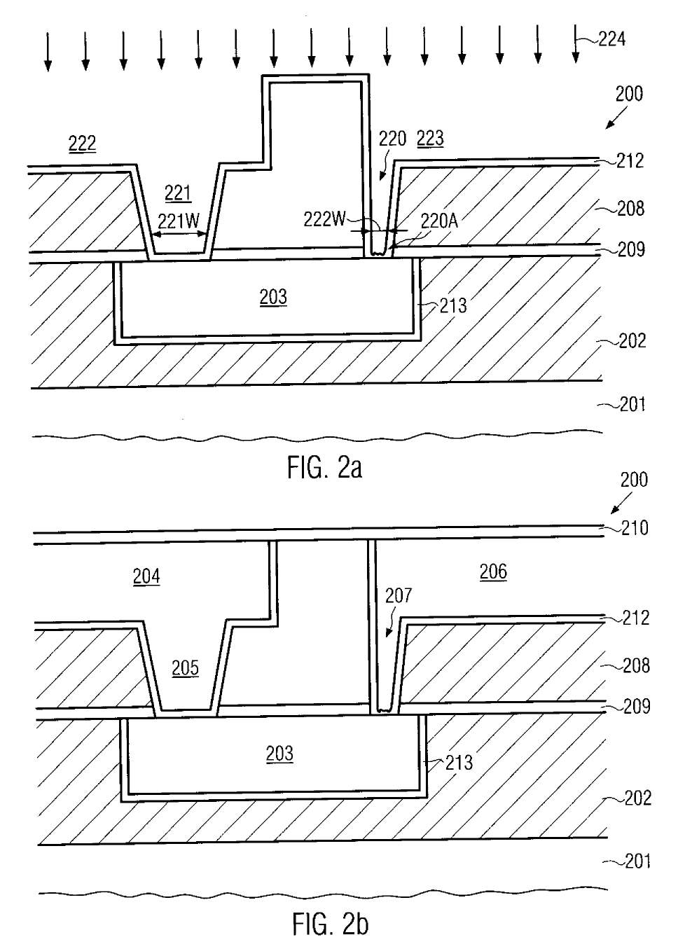

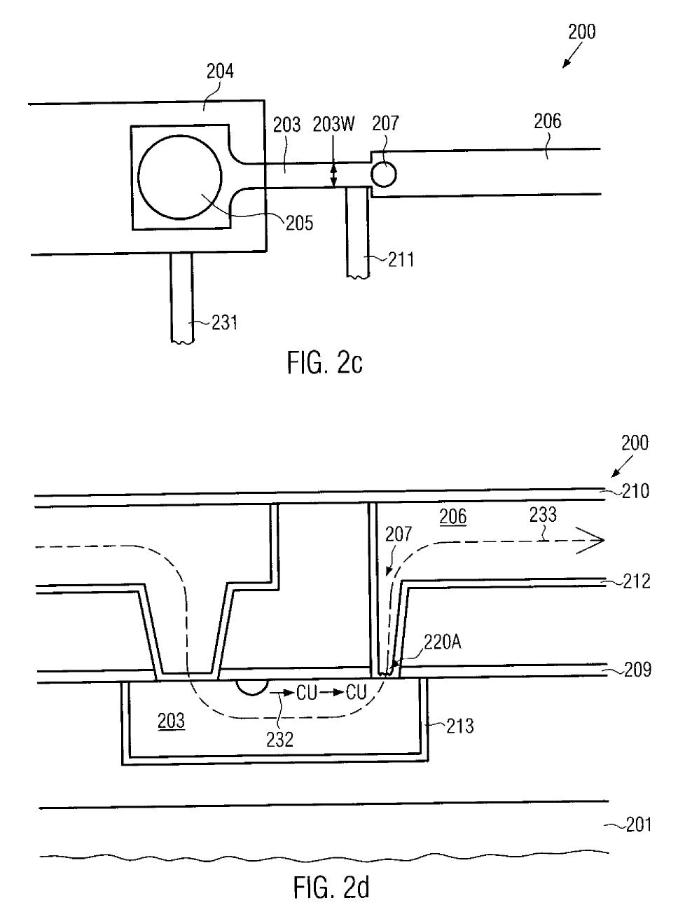

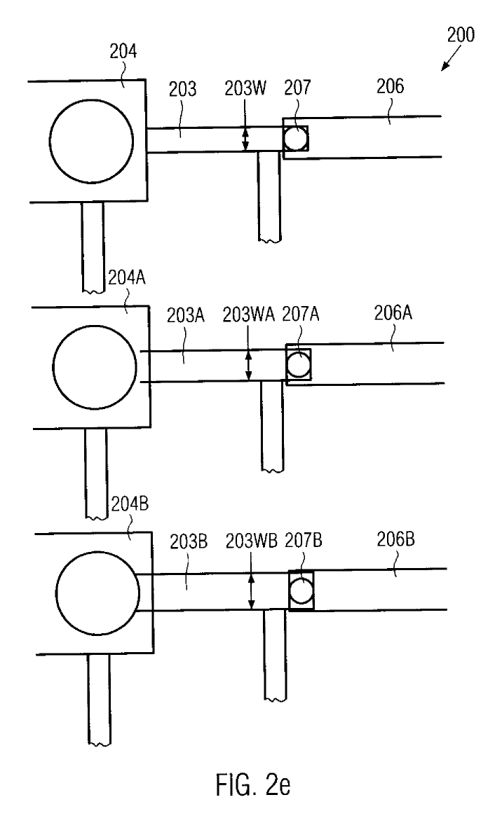

FIG. 2a schematically shows a cross-sectional view of a test structure 200 formed above a substrate 201, which may represent any appropriate substrate for forming thereon and therein semiconductor devices requiring a metallization structure, which may include a plurality of metallization layers as are typically provided in modern integrated circuits, wherein respective metal lines provide the interlevel electrical connection of circuit elements, whereas respective vias provide the connection of adjacent metallization layers. For instance, the substrate 201 may represent a silicon substrate, a silicon-on-insulator (SOI) substrate or any other appropriate carrier material having formed thereon respective semiconductor regions as required for the manufacturing of specific circuit elements, such as transistors, capacitors and the like. In some illustrative embodiments, the substrate 201 may have formed therein and thereon circuit elements such as transistors having a critical dimension, such as the gate length thereof, of 100 nm and significantly less. It should be appreciated that the test structure 200 may be formed above the substrate 201, which may have formed therein on respective die areas functional integrated circuits, while, in other illustrative embodiments, the substrate 201 may represent a dedicated test substrate above which the test structure 200 is fabricated, while substantially lacking functional integrated circuits. Above the substrate 201 and any device layer and lower-lying metallization layers, a dielectric layer 202 may be provided, for instance on the basis of any appropriate material, such as silicon dioxide, silicon nitride, low-K dielectric materials and the like. It should be appreciated that the dielectric layer 202 may represent the dielectric material of a specified metallization layer as may typically be formed in other areas of the substrate 201. The dielectric layer 202 may comprise therein a feed line 203, which may have a configuration so as to suffer from an increased electromigration effect under specified test conditions. For instance, the feed line 203 may be comprised of any appropriate metal, such as copper, copper alloy, aluminum and the like, depending on process requirements. For instance, if the test structure 200 is formed commonly with actual products above the substrate 201, the feed line 203 may be manufactured in accordance with specific manufacturing techniques. In this case, the desired characteristics of the feed line 203 may be adjusted on the basis of the respective design dimensions, i.e., the cross-sectional area of the feed line 203 may be appropriately selected, for instance, by selecting an appropriate width of the feed line 203, which represents the direction perpendicular to the drawing plane of FIG. 2a. That is, the feed line 203 is configured such that, for a given current density, the highest probability for void formation caused by electromigration may be achieved in the feed line 203 when a non-desired configuration of a barrier layer 212, formed in a respective test via 220, may result during a corresponding manufacturing process.

It should be appreciated that other characteristics of the feed line 203 may be appropriately adjusted in order to obtain the desired behavior. For instance, if the test structure 200 is fabricated on a dedicated substrate, such as the substrate 201, a certain degree of freedom with respect to the manufacturing process techniques for forming the feed line 203 may be provided which may enable a specific adjustment of the electromigration characteristics of the feed line 203, for instance by not only selecting the respective width but also selecting a specified thickness of the feed line 203, a specified type of material and/or a specific manufacturing technique for adjusting grain size and/or orientation and the like. For example, the dielectric layer 202 in combination with the feed line 203 may be formed on the basis of process strategies that may not correspond to the manufacturing flow of actual metallization layers, since metal features such as the feed line 203 may not actually be used in products. In this case, a plurality of parameters may be used in order to obtain the desired electromigration behavior. Hence, contrary to conventional designs, the feed line 203 is intentionally configured to provide high void formation during electromigration test conditions, when the barrier layer 212 in the test via 220 may have a substantially non-continuous configuration especially at a bottom 220A thereof. In the embodiment illustrated, it may be assumed that the feed line 203 and the dielectric layer 202 are formed in accordance with device and process requirements as are also used for the formation of actual semiconductor products. For example, if a copper-based metallization structure is considered, the feed line 203 may typically be confined by a barrier layer 213, such as a barrier material as previously indicated, wherein, in some illustrative embodiments, the barrier layer 213 may have substantially the same configuration as the barrier layer 212. Moreover, the feed line 203 may be confined on the top side thereof by a respective dielectric capping layer 209, for instance comprised of silicon nitride, silicon carbide, nitrogen-enriched silicon carbide, combinations thereof or any other appropriate dielectric capping layer. The layer 209 may also act as an efficient etch stop layer during the patterning of a dielectric layer 208, in which is formed the test via opening 220 and a respective test metal line opening 223. Moreover, a respective via opening 221 connected to a respective trench opening 222 may be formed in the dielectric layer 208 in order to provide a respective wiring structure for providing an electrical connection to an appropriate probe pad (not shown). It should be appreciated that the test via opening 220 and the respective trench opening 223 may be formed on the basis of typical device dimensions and manufacturing techniques in order to provide a high degree of authenticity with respect to corresponding metallization structures in actual product devices. For example, if the test structure 200 is formed commonly with actual products, the via opening 220 and the trench opening 223, at least along a specific length thereof, may have dimensions corresponding to actual metallization structures in the product areas of the substrate 201. Thus, the dielectric layer 208 may have any configuration identical to actual products and may be formed of a low-k dielectric material, a combination of several dielectric materials and the like. The same holds true for the barrier layer 212, which may be comprised of any appropriate barrier material as actually used in the manufacturing process for the semiconductor devices under consideration.

A typical process flow for forming the test structure 200 as shown in FIG. 2a may comprise the following processes. After the formation of any circuit elements, if provided, in and above the substrate 201, on the basis of well-established process techniques including well-established micromechanical and/or microelectronic manufacturing processes, the dielectric layer 202 may be formed on the basis of well-established deposition techniques, such as chemical vapor deposition (CVD), spin-on techniques and the like. Thereafter, the dielectric layer 202 may be patterned on the basis of photolithography and anisotropic etch techniques, followed by the deposition of the barrier layer 213, if provided, which may be accomplished on the basis of sputter deposition, electroless deposition, CVD and the like. Thereafter, a respective material, such as copper, copper alloys and the like, may be filled into the respective opening by electrochemical deposition techniques, such as electroplating, electroless plating and the like. It should be appreciated, however, as previously explained, that any other process sequence may be used, depending on process and device requirements, as specified above. Thereafter, if required, the resulting surface topography may be planarized, for instance by removing any excess material, and the dielectric barrier layer 209 may be formed on the basis of any appropriate deposition technique, such as CVD. Next, the dielectric layer 208 may be formed on the basis of process techniques as are also used in actual semiconductor devices, that is, for highly sophisticated semiconductor devices, typically the dielectric material 208 may comprise, at least partially, a low-k dielectric material, i.e., a dielectric material having a relative permittivity of 3.0 and significantly less. Since the finally obtained characteristics of a metallization structure with respect to electromigration are dependent on a plurality of mutually interacting characteristics, such as the diffusion behavior, which may significantly depend on the characteristics of the respective interfaces and the like, in particular embodiments, the same process recipes are used for forming the dielectric layer 208, even if the test structure 200 is formed on dedicated substrates that may not include any actual semiconductor products. Consequently, the respective via openings and trench openings 221, 220, 222 and 223 may also be formed on the basis of a specific process technique as is also used for the application of actual semiconductor products.

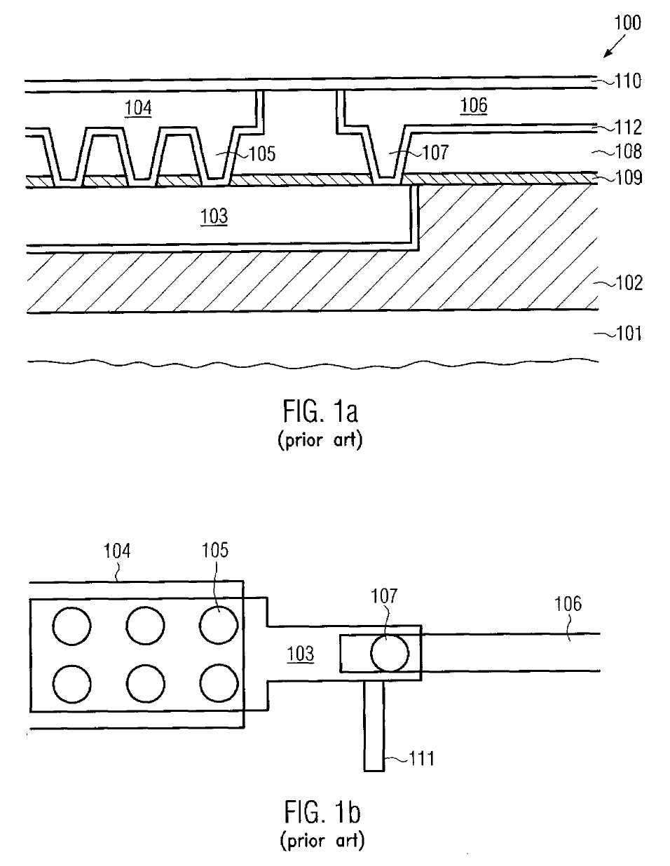

For example, in the embodiment illustrated, a so-called dual inlaid technique may be used, in which the respective via openings and trench openings are formed in the dielectric layer 208 according to any appropriate patterning regime, wherein the respective openings are then filled in a common metal deposition process. It should be appreciated that other process regimes may be used, for instance a single damascene regime, in which vias may be formed first and thereafter the respective metal lines may be formed. In one illustrative embodiment, during the patterning of the dielectric layer 208 for forming the via openings 221 and 220, the respective design dimensions 221W of the via 221 are selected such that a significantly increased probability for a reliable coverage of the respective via bottom is achieved during a subsequent deposition process 224, that is, the design width or diameter 221W of the via 221 may be selected greater compared to the width 220W of the actual test via 220 which substantially corresponds to actual vias as may be formed in the respective semiconductor devices. Similarly, the respective trench opening 222 connecting to the via 221 has a sufficient width so as to substantially eliminate any probability for developing electromigration effects with respect to predefined test conditions for an electromigration test to be performed with the test structure 200. After the patterning of the dielectric layer 208 on the basis of well-established techniques, the deposition process, such as a sputter deposition process or any other deposition process as typically used for the formation of actual metallization structures, may be performed, wherein, especially at high aspect ratio openings such as the test via opening 220, a significant risk for a non-continuous coverage at the via bottom 220A may exist. Consequently, a hole or a certain degree of porosity may be created especially at the bottom 220A, which may result, in actual metallization structures, in a different electromigration behavior and which may also result in less reliable lifetime estimations in conventional test structures, as previously explained with reference to FIGS. 1a-1b. In contrast to the via 220, the via opening 221 is substantially continuously covered by the barrier layer 212, since here the aspect ratio is significantly less, thereby relaxing the corresponding constraint for the deposition process 224.

FIG. 2b schematically illustrates the test structure 200 in a further advanced manufacturing stage. Here, respective openings have been filled with an appropriate metal, such as copper, copper alloy and the like, to provide a test via 207 connected to a respective test metal line 206 while a via 205 having a continuously covered bottom and the respective connector line 204 are provided. Moreover, a respective capping layer 210, for instance comprised of a dielectric material selected in accordance with device requirements, may be formed to confine the respective metal lines 206 and 204. As previously explained, the respective metals may be filled in according to a specified manufacturing flow including any post-deposition treatments to obtain the desired characteristics, for instance in terms of grain size, grain orientation and the like, and the same holds true for the formation of the capping layer 210.

FIG. 2c schematically illustrates a top view of the test structure 200 in accordance with illustrative embodiments, wherein it should be appreciated that the respective dielectric materials 210, 208 and 209 are not shown. In the embodiment shown, the characteristics of the feed line 203 with respect to its high probability for void formation during electromigration conditions for a reduced series resistance of the via 207, due to a porous or non-continuous barrier layer at the bottom (FIG. 2b), may be adjusted by appropriately selecting a width 203W in order to obtain a respectively reduced cross-sectional area, for instance, compared to the metal line 206, when a manufacturing process flow has been used, in which a thickness or depth of the respective metal lines is determined by the process flow. That is, if the respective etch depth during patterning the trench for the feed line 203 is defined by process flow specifics and may be substantially the same for the trench opening 223 of the metal test line 206, the width 203W may be appropriately selected as an efficient mechanism for adjusting the probability for void formation during an electromigration test. Similarly, due to the selection of the dimensions of the connector line 204 and the moderately high width or diameter of the via 205 connected to the feed line 203, a corresponding electromigration failure in case of a porous via 207 is substantially restricted to the feed line 203. Moreover, in the embodiment illustrated in FIG. 2c, respective voltage taps 211 and 231 may be provided such that a corresponding voltage may be detected at specified positions of the feed line 203. In the embodiment illustrated, the voltage tap 231 may be connected to the connector line 204 or to a first end of the feed line 203, while the second voltage tap 211 may be connected to the feed line 203 substantially at the end thereof before the test via 207. In this way, resistance changes occurring upstream of the voltage tap 231 and upstream of the voltage tap 211 may be efficiently determined. Moreover, by providing the respective voltage taps 231 and 211 at the respective ends of the feed line 203, a corresponding void formation may be efficiently detected along the entire length of the feed line 203. It should be appreciated, however, that the respective voltage taps 231, 211 may also be provided such that only a specific length of the feed line 203 may be monitored if desired.

FIG. 2d schematically illustrates a cross-sectional view of the test structure 200 as shown in FIG. 2c during operation. That is, predefined test conditions may be established. For instance, a certain temperature may be applied and a specific current may be injected into the test structure 200 on the basis of a corresponding current source (not shown), which may be connected to respective probe pads (not shown), one of which may be connected to the connector line 204 while another one may be connected to the metal line 206 downstream thereof. In the situation as shown in FIG. 2d, it may be assumed that a current flow is established, wherein electrons flow from the connector line 204 through the via 205 into the feed line 203 and further into the test via 207 and the test metal line 206. Hence, electromigration-induced material transport of metal atoms, such as copper, may take place along the flow direction of the electrons, as indicated by the arrow 233, thereby imparting on the copper atoms a net force in the direction of the anode of the respective current source. It should be appreciated that any information regarding the position of a component, such as upstream, downstream and the like, is to be considered as referred to the flow direction of electrons as shown in FIG. 2d. That is, in FIG. 2d, the feed line 203 is upstream with respect to the test via 207. It should be appreciated, however, that the inverse flow direction may also be selected, thereby obtaining a material transport in the inverse direction. During the test procedure, a high current may be injected into the test via 207 and the test metal line 206 in order to obtain a desired current density therein, which may significantly exceed the typical current densities established during standard operational conditions. Moreover, other stress conditions may be applied, for instance elevated temperatures or temperature gradients may be established in the test structure 200 and/or a mechanical stress may be applied in order to estimate the expected lifetime of the corresponding metallization structures in actual products.

As previously explained, during the test procedure, a high current density may prevail within the test via 207 and the test metal line 206, and also within the feed line 203, wherein the probability for a current-induced material transport, such as a copper flux as indicated by 232, may take place when a substantially non-continuous coverage of the via bottom 220A by the barrier layer 212 may have resulted during the manufacturing sequence. For example, as previously explained, the cross-sectional area of the feed line 203 or any other appropriate characteristic may be selected so as to be close to the minimum cross-sectional area or the minimum parameter value of the respective characteristic in order to obtain a preferred probability for suffering from current-induced material transport, when an interface between the feed line 203 and the via 207 at least a bottom portion of the via 207 may have a reduced coverage, thereby providing, for instance a reduced series resistance and the like. While in conventional techniques the corresponding feed line 103 is considered as not failing during an electromigration process, a significant over-estimation of the expected lifetime of a via, such as the via 207, having a non-continuous barrier layer may result, since a corresponding degradation of the respective feed line may remain undetected, while the modified electromigration behavior of the test via may result in an over-estimated lifetime of the test structure. In the feed line 203, the respective probability for electromigration failure may be increased in such a way that a material transport, i.e., a void formation, may be detected while, in some illustrative embodiments, additionally, respective measurement data may also be obtained from the test via 207, thereby providing the potential for estimating the status of the test via, including the test metal line 206, and the feed line 203.

In one illustrative embodiment, a respective resistance change at the voltage tap 231 (FIG. 2c) may be detected along with a respective resistance change obtained from the second voltage tap 211 (FIG. 2c), wherein a difference in the respective resistance changes may indicate the status of the feed line 203. For example, if a significant material transport, as indicated by 232, may have occurred during the test procedure, a respective resistance change may be detected upstream of a corresponding void, for instance may be detected at the voltage tap 231, while the second voltage tap 211 may result in substantially the same resistance value or may exhibit a reduced resistance value, depending on the specific characteristics, whether additional material may build up next to the via 207 or the metal line 206. Upon detecting a specified difference in resistance changes along a specific length of the feed line 203, the corresponding test via 207 may be assessed to lack a substantially continuous area layer 202 at the via bottom 220A. In some illustrative embodiments, the via 205 upstream of the feed line 203 may have a sufficient diameter for providing an intact barrier layer 212, so that the respectively detected difference in resistance changes may be assigned to the feed line 203, which may now be used as an indicator for estimating whether or not the corresponding structure under consideration, i.e., the test via 207 and the test metal line 206, may meet the design criteria with respect to the barrier layer 212 and may also give an indication on the reliability of the corresponding lifetime measurements. For example, if a corresponding measurement result indicates a significant void formation in the feed line 203, the corresponding test via 207 may be indicated as a non-continuously covered test via and the resulting lifetime values may not be used for estimating electromigration characteristics of respective product structures having substantially the same configuration as the test via 207 and the respective metal line 206. Consequently, the reliability of corresponding electromigration tests may be significantly enhanced, while at the same time an efficient technique for estimating the porosity of a test via is provided.

FIG. 2e schematically illustrates the test structure 200 in accordance with other illustrative embodiments of the present invention. In these embodiments, the test structure 200 may comprise two to more test vias connected to respective feed lines. As shown in FIG. 2e, a first test via may correspond to the test via 207 as shown in FIG. 2c, which is connected to the respective feed line 203. Similarly, a second test via 207A connected to a respective second test metal line 206A may be provided and connected via a respective feed line 203A to a respective connector line 204A by means of a respective via 205A. In other illustrative embodiments, three or more further test vias and metal lines 207B, 206B may be provided which may be connected via respective feed lines 203B to a connector line 204B on the basis of a via 205B. In some illustrative embodiments, the respective connector lines 204, 204A, 204B and the vias 205, 205A, 205B have substantially the same configuration. Similarly, the test vias 207, 207A, 207B and the metal lines 206, 206A, 206B may have substantially the same configuration, that is these components may be formed on the basis of the same process technique and with the same design dimensions so that, due to the close proximity to each other, it may be assumed that the respective manufacturing sequence may have resulted in substantially the same configuration of the respective via bottoms with respect to coverage by the barrier layer 212. Similarly, respective voltage taps 231A, 231B and 211A, 211B may be provided and may be connected to the feed lines 203A, 203B, respectively. It should be appreciated that, in some illustrative embodiments, the respective voltage taps may be routed to a corresponding probe pad on the basis of a switching element, such as a transistor, in order to allow the monitoring of the respective voltage taps 231, 231A, 231B, 211, 211A, 211B in a multiplexed manner, thereby saving respective probe pads. When the number of probe pads for obtaining the respective resistance change information via the voltage taps is uncritical, a corresponding number of probe pads may be provided. The various feed lines 203, 203A, 203B may differ in their probability for creating a void during specific electromigration conditions so as to allow a quantification of the status of the respected barrier layer in the various test vias 207, 207A 207B, from which it may be assumed that they have substantially the same configuration.

In one illustrative embodiment, the feed line 203 may have the highest probability, which may be achieved by selecting an appropriate cross-sectional area by selecting a specified line width 203W so as to obtain a relatively narrow metal line as indicated in FIG. 2e. Similarly, one of the feed lines 203A, 203B may have an increased width to obtain a lower probability for void formation compared to the feed line 203. For instance, a width 203WA of the feed line 203A may be greater than the width 203W but may be less than a corresponding width 203WB of the feed line 203B. Thus, during operation of the test structure 200 as shown in FIG. 2e, upon occurrence of a porous or non-continuous barrier layer in the respective test vias 207, 207A, 207B, a respective failure in the feed line 203 may occur first and may be detected. Additionally, a respective void formation may also be detected in the second feed line 203A, however, at a later time due to the reduced probability, i.e., in the illustrative embodiment, due to the increased line width 203WA compared to 203W. Similarly, the time to a respective failure in the feed line 203B may be even longer due to the further reduced probability, i.e., in this example, due to the further increased line width 203WB compared to the line width 203WA, wherein the increased line width 203WB may still provide a higher capability of void formation compared to the metal test lines 206, 206A, 206B. Consequently, by obtaining the respective measurement results, i.e., the respective resistance changes at first and second positions of the respective feed lines 203, 203A, 203B, a quantitative estimation of the degree of porosity of the respective barrier layer 212 may be obtained. For this purpose, from the respective time intervals for failure, i.e., for obtaining a predefined value of the difference of resistance changes in the respective feed lines 203, 203A, 203B, the degree of porosity may be quantified. For example, respective cross-sectional analysis, such as scanning electron microscopy (SEM) measurements, may be used as a reference. A corresponding correlation between actual cross-sectional analysis results and the respective measurement results may be performed only once or a few times in order to obtain the desired reference. In other cases, the respective measurement results themselves may be used as a quantitative measure for the status of the barrier layer 212 without a specific reference to reference data, thereby providing the potential for assessing the respective configurations on the basis of the electromigration results. For instance, a respective electromigration failure after a moderately long time interval in the feed line 203B may indicate a severe degree of porosity of the barrier layer in the test vias 207, 207A, 207B compared to respective test vias of a different structure in which a corresponding electromigration failure may be detected in the feed line 203B after a shorter time interval. For example, the various test vias may have been formed on the basis of different design diameters in each of a plurality of different test structures, such as the structure 200 as shown in FIG. 2e, thereby providing the potential for not only estimating the degree of porosity for a specific test via, but also to compare the status of the respective barrier layer for a plurality of different test via configurations. Moreover on the basis of the respective resistance changes in the vicinity of the respective test vias 207, 207A, 207B, the status of the respective test vias and test metal lines may also be estimated, for instance on the basis of the corresponding feed line 203B having the lowest probability for electromigration failure. In this case, the expected lifetime of vias having substantially the same configuration as the test vias 207, 207A, 207B may be estimated simultaneously with assessing the status of the respective barrier layer. In still other illustrative embodiments, the width of a corresponding feed line may be increased such that it may have a larger effective cross-sectional area and, thus, reduced probability for void formation compared to the metal line, such as the metal line 206, thereby producing a moderately high lifetime of the feed line and a less efficient void formation mechanism in order to allow a meaningful estimation of the actual electromigration behavior of the respective test via and the metal line connected thereto.

As a result, the subject matter disclosed herein provides a new test structure and a corresponding test procedure associated therewith in order to efficiently determine the status of a barrier layer in a test via during an electromigration test procedure by providing a feed line having an increased probability for void formation when a non-intact barrier layer is formed at the via bottom. This may be accomplished by providing the respective feed line with a significantly reduced cross-sectional area, such as a reduced line width, which may substantially correspond to or may be close to a minimum line width for withstanding the electromigration effect for a specified time interval for a substantially continuously covered via bottom of the test via. Consequently, upon a certain degree of porosity or other defects of the barrier layer, a correspondingly modified electromigration behavior may induce an efficient material transport in the feed line, which may then be efficiently detected as respective resistance changes at several positions at the feed line. Consequently, respective electromigration tests performed on the basis of conventional test structures may be “verified” with respect to barrier defects in the respective via bottom by additionally providing a corresponding test structure as described above. In other cases, the respective test structure may be designed such that a quantitative estimation of the degree of barrier defects may be obtained, thereby providing an efficient means for estimating the respective process flow used for manufacturing the respective test vias and, thus, respective metallization structures in actual semiconductor products. In still other embodiments, the respective test structures may also be used simultaneously estimating the electromigration behavior of the respective test vias, irrespective of whether a test indicates a porous barrier layer and the like.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A test structure, comprising:
a test via and a test metal line connected therewith, said test via and said test metal line formed in a metallization layer located above a substrate appropriate for forming semiconductor devices for an integrated circuit thereon, said test via and said test metal line comprising a conductive barrier layer;
a feed line connected to said test via, a cross-section area of said feed line being less than a cross-section area of said test metal line; and
a connector line connected to said feed line.

2. The test structure of claim 1, further comprising at least one via connecting said feed line and said connector line, said at least one via having a width that is greater than a width of said test via.

3. The test structure of claim 1, further comprising a connection assembly configured to determine a resistance change proximate both ends of said feed line.

4. The test structure of claim 2, wherein said at least one via comprises a barrier layer and wherein a thickness of said barrier layer at a bottom of said at least one via is greater than a thickness of said barrier layer at a bottom of said test via.

5. The test structure of claim 1, wherein said metallization layer represents a metallization layer formed on the basis of copper and a low-k dielectric material.

6. A test structure for estimating electromigration effects in a metallization layer of a semiconductor device, the test structure comprising:
a first test via comprising a barrier layer and a metal; and
a feed line connected to said first test via, said feed line configured to have a first higher probability for void formation compared to said first test via when said barrier layer is substantially non-continuously formed on a bottom of said first test via to provide a substantially non-continuous interface with said feed line.

7. The test structure of claim 6, further comprising a test metal line connected to said first test via and located downstream thereof.

8. The test structure of claim 7, further comprising a connector line provided for said feed line, said connector line being connected to said feed line by at least one via, said at least one via comprising said barrier layer continuously covering a bottom of said at least one via.

9. The test structure of claim 8, wherein a diameter of said at least one via is greater than a diameter of said first test via.

10. The test structure of claim 8, wherein a cross-sectional area of said feed line is less than a cross-sectional area of said test metal line and a cross-sectional area of said connector line.

11. The test structure of claim 6, further comprising a first and a second voltage tap connected to said feed line.

12. The test structure of claim 11, wherein said first and second voltage taps are connected to determine a voltage at each end of said feed line.

13. The test structure of claim 6, further comprising a second test via including said barrier layer and a second feed line, said second feed line having a second higher probability for void formation compared to said second test via when said barrier layer is substantially non-continuously formed on a bottom of said second test via to provide a substantially non-continuous interface with said second feed line.

14. The test structure of claim 13, wherein said first and second feed lines are configured to provide said first higher probability to be higher than said second higher probability.

15. The test structure of claim 14, wherein a width of said first feed line is less than a width of said second feed line.

16. The test structure of claim 6, wherein said metallization layer represents a metallization layer of a semiconductor device comprising transistor elements having a gate length less than approximately 100 nm.

17. A method, comprising:
injecting a specified current into a test structure, said test structure comprising a first test via and a first feed line connected to said first test via, said first feed line having a higher probability for void formation during injecting said specified current compared to said first test via when lacking a substantially continuous barrier layer on a bottom thereof;
obtaining a first resistance change at a first position and a second resistance change at a second position of said first feed line; and
estimating a status of said barrier layer at the bottom of said first test via on the basis of said first and second resistance changes.

18. The method of claim 17, further comprising using at least one of said first and second resistance changes for evaluating an electromigration characteristic of said test structure when said status of the barrier layer of said first test via is estimated to be substantially continuously covering the bottom of said first test via.

19. The method of claim 17, wherein said status of the barrier layer of said first test via is estimated to be non-continuous when said first and second resistance changes are different.

20. The method of claim 17, further comprising:
injecting said specified current into a second feed line connected to a second test via having substantially the same configuration as said first test via, said second feed line having a higher probability for void formation during injecting said current compared into said second test via when lacking a substantially continuous barrier layer on a bottom thereof;
obtaining a first resistance change at a first position and a second resistance change at a second position of said second feed line; and
using said first and second resistance changes of the second feed line for estimating said status of the barrier layer of said first test via.
